(19) United States
(12) Patent Application Publication
(10) Pub. No.: US 2024/0419402 A1
(43) Pub. Date: Dec. 19, 2024

(54) ZERO-DETECTION FOR LOGIC CIRCUIT MULTIPLICATION

(71) Applicant: Microsoft Technology Licensing, LLC, Redmond, WA (US)

(72) Inventors: Evgeny ROYZEN, Kiryat Ono (IL); Ori LASLO, Rehovot (IL); Yaron Baruch SHAPIRO, Petach Tikva (IL)

(73) Assignee: Microsoft Technology Licensing, LLC, Redmond, WA (US)

(21) Appl. No.: 18/334,858

(22) Filed: Jun. 14, 2023

(51) Int. Cl. G06F 7/523; G06F 7/544; G06F 7/74; H03K 19/20

(52) U.S. Cl. CPC G06F 7/523; G06F 7/5443; G06F 7/74; H03K 19/20

(57) ABSTRACT

A logic circuit includes an input data line, and a zero-detection element configured to output a latch control signal with a first state based at least in part on detecting that a current input value on the input data line is equal to zero. A latch is configured to receive the current input value and output a latch output value, wherein the latch output value is a prior input value based at least in part on the latch control signal having the first state, and wherein the latch output value is the current input value based at least in part on the latch control signal having a second state. A multiplier performs a multiplication operation based at least in part on the latch output value.

### BACKGROUND

Logic circuits are widely used in various electronic systems and devices to perform different computational tasks. These circuits typically consist of a combination of digital components, such as gates, flip-flops, and multiplexers, which process input signals and generate output signals based on predefined logic operations.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A logic circuit includes an input data line, and a zero-detection element configured to output a latch control signal with a first state based at least in part on detecting that a current input value on the input data line is equal to zero. A latch is configured to receive the current input value and output a latch output value, wherein the latch output value is a prior input value based at least in part on the latch control signal having the first state, and wherein the latch output value is the current input value based at least in part on the latch control signal having a second state. A multiplier performs a multiplication operation based at least in part on the latch output value.

### BRIEF DESCRIPTION OF THE DRAWINGS

FIG. 1 schematically shows an example computing system including an arithmetic logic unit (ALU).

FIG. 2 illustrates an example logic circuit for performing multiplication operations.

FIG. 3 illustrates changes in signal values during operation of the logic circuit of FIG. 2.

FIG. 4 illustrates another example logic circuit including a multiplier-accumulator (MAC).

FIG. 5 illustrates an example method for data multiplication in a logic circuit.

FIG. 6 schematically shows an example computing system.

### DETAILED DESCRIPTION

It is generally desirable to reduce the electrical power consumed by computing devices. In particular, the growing demand for high-performance data processing (e.g., artificial intelligence, machine learning) has led to a corresponding rise in power consumption. This power usage not only contributes to increased operational costs but also poses challenges in terms of heat dissipation and environmental sustainability.

Accordingly, the present disclosure is directed to a logic circuit design that performs data multiplication operations and beneficially consumes less electrical power when one or more input values are “sparse”—e.g., equal to zero. As non-limiting examples, audio data, image data, tensors, neural network kernels, and other types of datasets sometimes include sparse data depending on the implementation. Specifically, the logic circuit described herein includes a zero-detection element configured to detect when a current input value carried by an input data line is equal to zero. For instance, the zero-detection element may include a suitable combination of logic gates (e.g., OR gates, AND gates) that output a control signal with different states depending on whether a value of zero is detected on the input data line. The logic circuit also includes a latch that receives the current input value and outputs a latch output value. The latch output value is received by a hardware multiplier, which performs a multiplication operation based on the latch output value—e.g., by multiplying it with a second input value.

Notably, the behavior of the latch is controlled by the control signal (referred to as a “latch control signal”) output by the zero-detection element. At times where the latch control signal has one state, the latch output value is the same as the current input value. However, at times where the latch control signal has a different state, the latch output value is instead equal to a prior input value that was received previously. In other words, based at least in part on a detection that the current input value on the data line is non-zero, the output of the latch is the same non-zero value, which is then received by the multiplier. However, if the current input value changes to zero, then the zero-detection element changes the behavior of the latch, such that the latch continues to output the same non-zero output value as before the input changed to zero—in other words, the input value to the multiplier does not change. In a typical system, such changes in the input value may occur following an edge in the system's clock cycle, for instance. Because the input value to the multiplier does not change, the multiplier does not consume additional electrical power.

In this manner, the power consumption of the overall computing system can be significantly reduced when it is performing computational operations on sparse datasets—e.g., those where significant portions of the input data values are null or equal to zero. This provides the technical benefit of reducing consumption of computational resources—e.g., less electrical power is consumed. Furthermore, the techniques described herein beneficially adapt to sparse data on-the-fly and without adding significant complexity. This provides the technical benefit of reducing the computational overhead often required for handling sparse data. Furthermore, the techniques described herein can beneficially be used in cases where the logic circuit includes a systolic array. Other hardware-based approaches to zero-detection often involve selectively disabling the clock signal for some components of the circuit when an input value is detected to be zero. However, this would interfere with propagation of data throughout a systolic array. The techniques described herein beneficially preserve compatibility with systolic arrays.

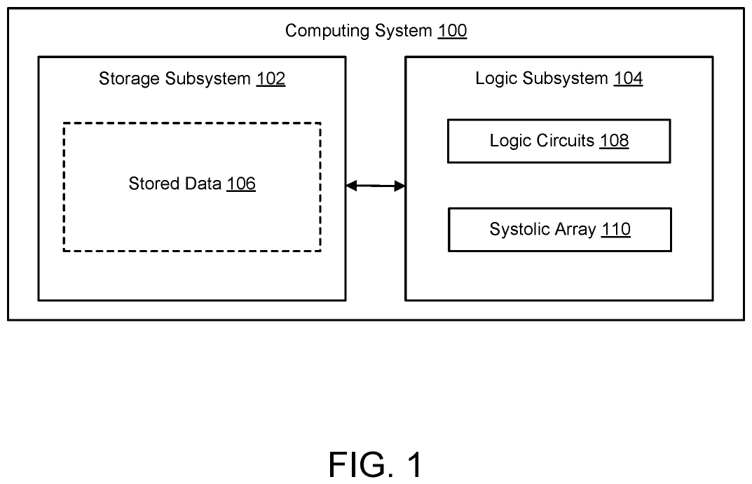

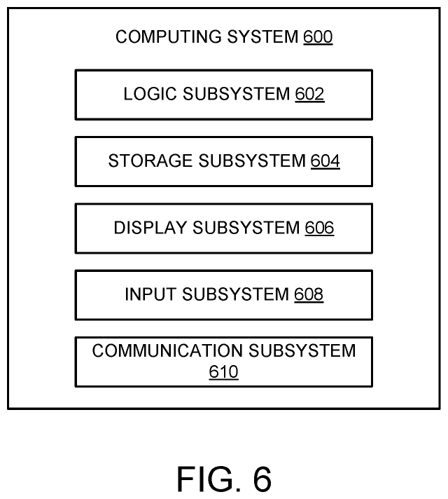

Data processing in a computing system is schematically illustrated with respect to FIG. 1, showing an example computing system 100. It will be understood that computing system 100 is highly simplified and intended only for the sake of explanation. Computing system 100 may comprise one or more discrete computing devices, each having any suitable capabilities, hardware configuration, and form factor. In some examples, computing system 100 may be implemented as computing system 600 described below with respect to FIG. 6.

As shown, computing system 100 includes a storage subsystem 102 and a logic subsystem 104. Each of these are generally implemented using any suitable technologies, as described below with respect to FIG. 6. In this example, the storage subsystem holds stored data 106, which may be any arbitrary computer data. As one non-limiting example, at least some of the stored data may include data that is provided to a machine learning model for processing, and/or generated by a machine learning model as an output.

The data is processed by the logic subsystem. Particularly, in this example, the logic subsystem includes one or more hardware logic circuits 108, configured to perform various operations on the input data. Such operations may include basic arithmetic functions like addition, subtraction, multiplication, and division, and/or logical operations such as AND, OR, XOR, and NOT, as well as bit shifting operations. It will be understood that the logic subsystem includes any suitable number and variety of different discrete hardware logic circuits, each having any suitable capabilities and configured to perform any suitable operations on input data.

Furthermore, in FIG. 1, the logic subsystem includes a systolic array. It will be understood that the computing system may include any suitable number and variety of systolic arrays, configured to perform any suitable operations on input data. A systolic array may be described as a specialized sub-type of logic circuit 108. In general, a systolic array takes the form of a highly parallel and structured computational architecture consisting of multiple processing elements arranged in a regular grid-like pattern. Systolic arrays are typically designed to efficiently perform repetitive computations by enabling data to flow through the array in a synchronized and pipelined manner. Each processing element operates concurrently and communicates with its neighboring elements through a fixed set of connections.

As discussed above, computer logic hardware (e.g., logic circuits, systolic arrays) generally consume electrical power while in use. Depending on the context, such power consumption can become significant. Furthermore, in some cases, the stored data provided to the logic hardware for processing may include some degree of sparsity—e.g., a nontrivial amount of the input data values are null, absent, or equal to zero—and this can present an opportunity to conserve electrical power. However, typical approaches to handling data sparsity often involve selectively disabling a clock signal for one or more components of a logic circuit, preventing those components from operating or consuming power. Such an approach would interfere with flow of data through the systolic array, rendering it unfeasible in many scenarios, as described above.

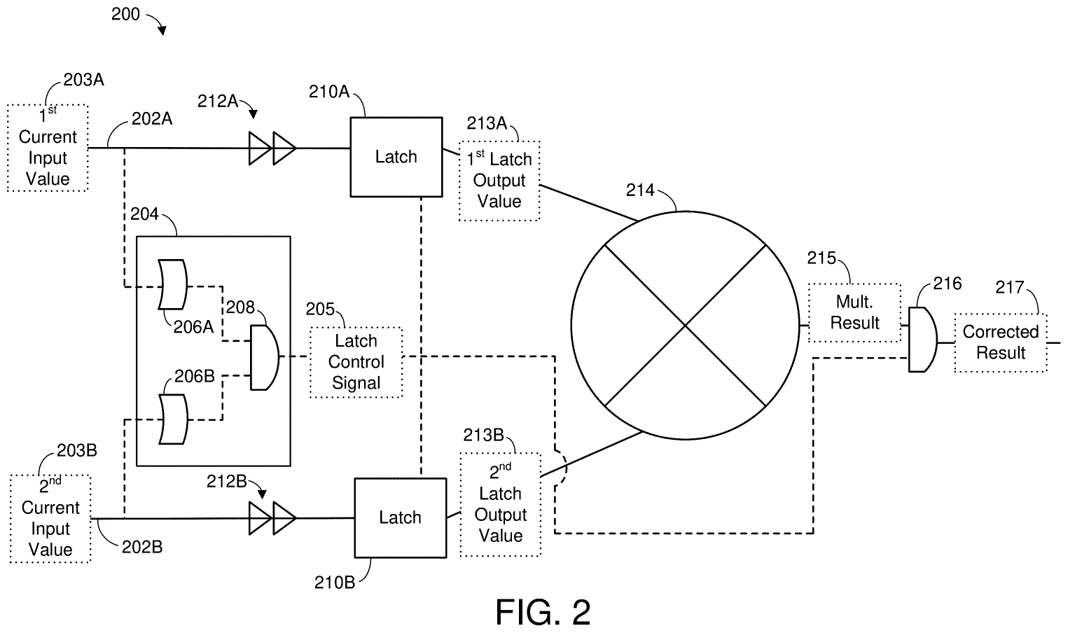

As such, FIG. 2 schematically depicts an example logic circuit 200 useable to perform multiplication operations, while beneficially reducing consumption of electrical power when an input data value is equal to zero. As shown, logic circuit 200 includes an input data line 202A that carries a current input value 203A into the logic circuit for processing. As will be described in more detail below, the logic circuit depicted in FIG. 2 additionally includes a second input data line 202B carrying a second current input value 203B, where the two current input values are intended for multiplication by the logic circuit.

The present disclosure generally refers to “input data lines” as being singular in nature. However, it will be understood that an input data line as described herein may carry any suitable number of bits of data—e.g., 8-bits, 16-bits, 32-bits, and so on. For instance, in the context of an 8-bit input data line, there may be eight separate electrical pathways or wires, each dedicated to carrying one bit of data. These parallel traces allow multiple bits of data to be transmitted simultaneously, improving the efficiency and speed of data transfer. In this configuration, each of the eight traces carries one bit of an 8-bit binary number, enabling the transmission of a complete 8-bit value in parallel. The eight traces (or other suitable number of traces depending on the implementation) are referred to collectively as an “input data line” that carries a “current input value.”

It will be understood that the current input values carried by any input data lines to the logic circuit take any suitable form, have any suitable numerical values, and are expressed using any suitable number of data bits. In one non-limiting example, one or more current input values to the logic circuit are generated during execution of a machine learning model by a computing system—e.g., computing system 100. For instance, the input values may include values from an input vector, network weight values, bias values, and/or any other suitable parameters. Non-limiting examples of technologies relating to machine learning and artificial intelligence will be described below with respect to FIG. 6. It will be understood that logic circuit 200 may perform data multiplication operations in any suitable computing context, and need not be used specifically in conjunction with machine learning or artificial intelligence.

In FIG. 2, the logic circuit additionally includes a zero-detection element 204 communicatively coupled to input data line 202A. The zero-detection element is configured to output a latch control signal 205 with a first state based at least in part on detecting that a current input value on the input data line is equal to zero. Depending on the implementation, the first state of the latch control signal may be a binary low value (e.g., a voltage corresponding to a digital zero), or the first state may be a binary high value (e.g., a voltage corresponding to a digital one). It will be understood that any time binary values are described throughout the present disclosure, such values may be inverted in some embodiments while still providing the functionality described herein.

In the example of FIG. 2, the zero-detection element is also communicatively coupled to the second input data line 202B, and outputs the latch control signal with the first state based at least in part on detecting that either or both of the current input value and the second current input value is equal to zero. In other words, if the current input value 203A is equal to zero, and/or the second current input value 203B is equal to zero, then the latch control signal is output with the first state. If neither of the first input value nor the second input value is equal to zero, then the latch control signal is output with a second state, which may be a binary opposite to the first state of the latch control signal. For instance, if the first state of the latch control signal is a binary zero, then the second state may be a binary one, and vice versa.

The zero-detection element is implemented in any suitable way and comprises any suitable number and variety of sub-components. In the example of FIG. 2, zero-detection element 204 includes two OR gates 206A and 206B, respectively coupled to the first input data line 202A and the second input data line 202B. In cases where every data individual data wire or trace of the input data line (e.g., eight traces in the case of an 8-bit circuit) carries a zero value, then the OR gate will also output a zero. As such, when the current input value on input data line 202A is equal to zero, then OR gate 206A will output a zero. Similarly, in cases where the second current input value 203B is equal to zero, then OR gate 206B will output a zero. The zero-detection element additionally includes an AND gate 208, which outputs a binary zero in cases where either of its inputs is equal to zero—e.g., if the current input value 203A or the second current input value 203B is equal to zero, then AND gate 208 outputs a binary zero as the latch control signal. As discussed above, it will be understood that these binary values are non-limiting, and that any or all of the binary values may be inverted while still providing the disclosed functionality.

In any case, logic circuit 200 also includes a latch 210A configured to receive the current input value 203A. The behavior of the latch is controlled by the latch control signal 205. In the example of FIG. 2, logic circuit 200 additionally includes a second latch 210B that receives the second current input value 203B, and is also controlled by latch control signal 205. As such, the latches may be described as “transparent” latches, as the input is passed to the output transparently when the latch is “enabled” by the latch control signal.

In some examples, it is desirable to control the rate of data propagation through the logic circuit. For example, if the current input value changes from a non-zero value to a zero value, the latch control signal should change its state and change the behavior of the latch before the latch receives the zero value as an input. This beneficially serves to avoid scenarios where latch control signal changes too slowly, and thus the latch passes the zero value to the multiplier. As such, in the example of FIG. 2, the input data line includes one or more delay cells 212A disposed along the input data line 202A, between the zero-detection element 204 and the latch 210A. Delay cells 212B are additionally disposed along second input data line 202B. These function to slow propagation of the current input value to the latch, while allowing the zero-detection element to change the state of the latch control signal if necessary. In this manner, if the current input value changes to a zero value, the latch control signal updates the behavior of the latch before the latch receives the zero value and passes it to the multiplier. This beneficially ensures that the mathematical output of the operation is correct, even in scenarios where power consumption was reduced in response to detection of sparsity.

The delay cells may be implemented in any suitable way. In some examples, a delay cell includes an inverter or a chain of inverters connected in series. By arranging one or more inverters in series, the signal passing through the delay cell experiences a cumulative delay due to the propagation delay of each individual inverter. The number of inverters, and the specific characteristics of each inverter, may be varied depending on the implementation and depending on the specific amount of delay that should be introduced.

In any case, latch 210 outputs a latch output value 213A. The actual value of the latch output value is dependent on the current state of the latch control signal. Specifically, in cases where the latch control signal has the first state (e.g., a binary low value), the current input value is not actually output by the latch as the latch output value. Instead, the latch output value is a prior input value—e.g., the output value does not change because the input to the latch changed. At times where the latch control signal has the second state (e.g., a binary high value), the latch output value is the same as the current input value. As a result, when the current input value on the input data line is non-zero, it is both received by the latch, and output by the latch for multiplication. However, if the current input value changes to zero, then the latch continues outputting its previous input value—e.g., the latch output value is not changed to zero.

Similarly, in the example of FIG. 2, logic circuit 200 also includes a second latch 210B that receives the second current input value, and outputs a second latch output value 213B. As with first latch 210A, the second latch is controlled by the latch control signal, thereby affecting the second latch output value. For instance, in one example, the second latch output value is a second prior input value based at least in part on detecting that the latch control signal has the first state, and the second latch output value is the second current input value based at least in part on detecting that the latch control signal has the second state.

The latch output values are received by a multiplier 214 configured to perform a multiplication operation based on the latch output values it receives. For instance, in the example of FIG. 2, the first latch output value is multiplied by the second latch output value to give a multiplication result 215. It will be understood that the multiplier may be implemented in any suitable way. In general, a hardware multiplier takes two binary operands, typically represented as sets of bits, and produces their product as the output. It operates on the principles of binary multiplication, employing a combination of logic gates, multiplexers, and/or registers to execute the multiplication algorithm. For instance, the binary operands may be fed into a series of stages or partial product generators. Each stage generates partial products corresponding to the multiplication of a single bit of the multiplier with the multiplicand. These partial products are then combined and accumulated to obtain the final product—e.g., multiplication result 215.

Notably, as discussed above, the inputs to the multiplier are affected by the latch control signal, which changes depending on whether the current input values on the input data lines are equal to zero. For instance, based at least in part on the first current input value 203A and the second current input value 203B being non-zero values, input value 203A is passed by latch 210A to the multiplier. However, in cases where either of the input values are qual to zero, input value 203A is not passed by latch 210A to the multiplier. Instead, the multiplier continues to receive a prior input value that was received previously, as described above. In the example of FIG. 2, this also applies to the second current input value. Thus, when both of the current input values are non-zero, the multiplier receives the non-zero values and multiplies them, as expected. However, when one or both of the input values are equal to zero, then the inputs to the multiplier do not change-instead, the multiplier continues receiving the same input values as it received previously, when neither of the input values was equal to zero, and the multiplication result 215 output by the multiplier does not change. This beneficially reduces power consumption, as power is not consumed by the multiplier when its inputs do not change.

Notably, the above approach reduces the power consumption of the multiplier, but also causes the multiplier to output an incorrect result in cases where one or both of the current input values are equal to zero. In other words, the multiplication result output by the multiplier will still be the product of two non-zero input values received previously, when mathematically, the multiplication result should be equal to zero (as one or both input values are equal to zero).

Accordingly, in the example of FIG. 2, logic circuit 200 additionally includes a multiplication correction element 216 configured to receive the result of the multiplication operation from the multiplier, and output a corrected value of zero when the latch control signal has the first state. As shown, multiplication correction element 216 outputs a corrected result 217. Specifically, multiplication correction element 216 is implemented as an AND gate, where the inputs to the AND gate include the output of the multiplication operation and the latch control signal. Thus, in this case, the output of the AND gate is equal to zero whenever the latch control signal is a binary zero, regardless of the value of the multiplication result. If, however, the latch control signal is not equal to zero, then the multiplication correction element may output the multiplication result from the multiplier without modification. This beneficially enables a reduction in power consumption at times when one or both of the input values are equal to zero, without affecting the accuracy of the multiplication result—e.g., the system beneficially does not miss an opportunity to conserve power when an input value is equal to zero. It will be understood that the multiplication correction element may be implemented in any suitable way—e.g., using any suitable combination of gates and other logic components to provide the disclosed functionality.

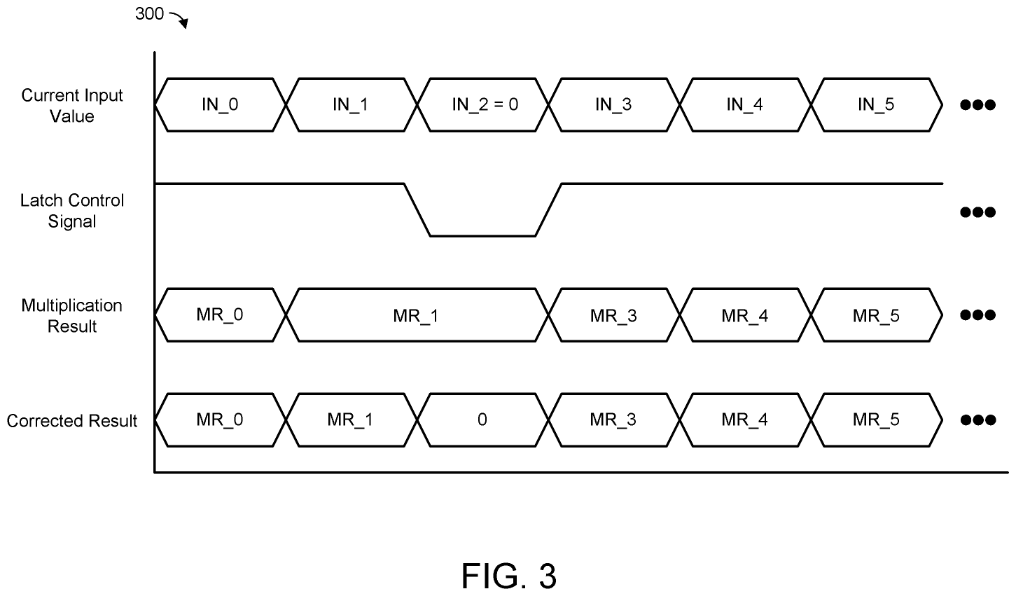

FIG. 3 provides a simplified illustration of how different signal values change over time during operation of a logic circuit, such as logic circuit 200. Specifically, FIG. 3 is a plot 300 showing changes in the current input value, latch control signal, multiplication result, and corrected multiplication result over time. As shown, the current input value changes over time between several different values, including IN_0-IN_5. One of the input values, IN_2, is equal to zero. As shown, after the current input value changes to zero, the state of the latch control signal changes—e.g., from high to low in this case. This affects the multiplication result output by the multiplier. Specifically, after the current input value changes from a non-zero value (IN_1) to a zero value (IN_2), the multiplication result is not affected—the multiplier continues to output a value MR_1. This beneficially reduces power consumption by the logic circuit, as discussed above. Furthermore, in FIG. 3, the corrected multiplication result has a value of zero at times where the current input value is zero. Otherwise, the corrected multiplication result remains equal to the original multiplication result.

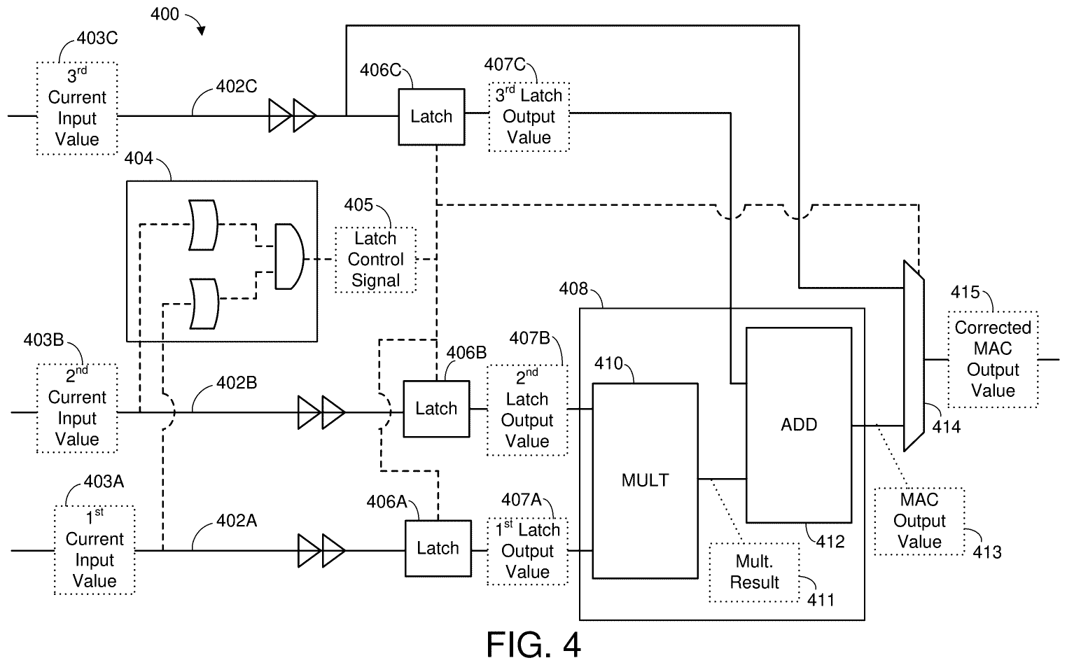

Notably, the example logic circuit 200 shown in FIG. 2 is used for data multiplication only. In some examples, however, the multiplier is a part of a multiplier-accumulator (MAC) configured to multiply two values, and add a third value. This is schematically illustrated with respect to FIG. 4, showing another example logic circuit 400. As shown, logic circuit 400 includes a first input data line 402A, a second input data line 402B, and a third input data line 402C, each carrying respective current input values 403A-403C. The overall circuit is used to multiply the first current input value with the second current input value, and then add the third current input value to the multiplication result. However, as with logic circuit 200, the behavior of logic circuit 400 changes when either or both of the first current input value and the second current input value is equal to zero.

Specifically, as with logic circuit 200, logic circuit 400 includes a zero-detection element 404 that checks whether the first current input value or the second current input value is equal to zero. The zero-detection element outputs a latch detection signal 405 with a state that depends on whether a zero value is detected—e.g., the latch control signal has a first state based at least in part on one or both of the input values being equal to zero, and a second state if both input values are non-zero.

The current input values on each input data line are received by respective latches 406A-406C. As described above, each latch outputs a corresponding latch output value 407A-C, based on the current state of the latch control signal. For instance, as with the first latch and second latch described above, the third latch 407C receives the third current input value from the third data line, and outputs a third latch output value. In this example, the third latch output value is a third prior input value based at least in part on the latch control signal having the first state (e.g., a binary low value), and the third latch output value is the third current input value based at least in part on the latch control signal having the second state (e.g., a binary high value). Thus, as with the example of logic circuit 200, the latches of logic circuit 400 output their current input values if neither the first nor the second current input values are equal to zero, and output prior non-zero input values if either of the first or second input values are equal to zero.

The latch output values are provided to a MAC 408. Specifically, the first latch output value 407A and the second latch output value 407B are provided to a multiplier 410 of the MAC, which multiplies the values and outputs a multiplication result 411. The multiplication result and the third latch output value 407C are each provided to an accumulator 412 of the MAC, which adds the third latch output value to the multiplication result and outputs a MAC output value 413. Similar to logic circuit 200, the MAC only consumes electrical power when its inputs change. As described above, when either the first or the second current input value is equal to zero, the latch output values are not updated, and thus the inputs to the MAC do not change. As such, logic circuit 400 beneficially enables a reduction in electrical power consumption when either of the first or second current input values are equal to zero.

As with logic circuit 200, the above approach reduces the power consumption of the MAC, but also causes the MAC to output an incorrect result in cases where either of the first current input value and the second current input value are equal to zero. In other words, the multiplication result output by the multiplier of the MAC will still be the product of two non-zero input values received previously, when mathematically, the multiplication result should be equal to zero (as one or both input values are equal to zero). The incorrect multiplication result is then added to the third latch output value, which is also a previous input value (e.g., not equal to the third current input value), and thus the MAC output value is also incorrect.

As such, in the example of FIG. 4, logic circuit 400 additionally includes a multiplexer 414 configured to receive the MAC output value and the third current input value. Notably, the multiplexer receives the third current input value rather than the third latch output value. In other words, even if either or both of the first current input value and the second current input value is equal to zero, causing the latches to output prior input values instead of passing the current input values to the MAC, the multiplexer still receives the actual third current input value. The multiplexer also receives, and is controlled by, the latch control signal. In this manner, the multiplexer is configured to output the third current input value as a corrected MAC output value 415 based at least in part on determining that the latch control signal has the first state. This is a mathematically correct output of the logic circuit, as this situation arises if either or both of the first current input value or the second current input value is equal to zero. In such cases, the correct multiplication result would be zero, and the correct result after addition would simply be equal to the third current input value. In cases where both the first current input value and the second current input value are non-zero values, the MAC output value 413 is mathematically correct, and is output by the multiplexer instead of the third current input value. Notably, this also beneficially reduces power consumption of the adder aspect of the MAC, as the final output value (e.g., third current input value) is output directly via the multiplexer.

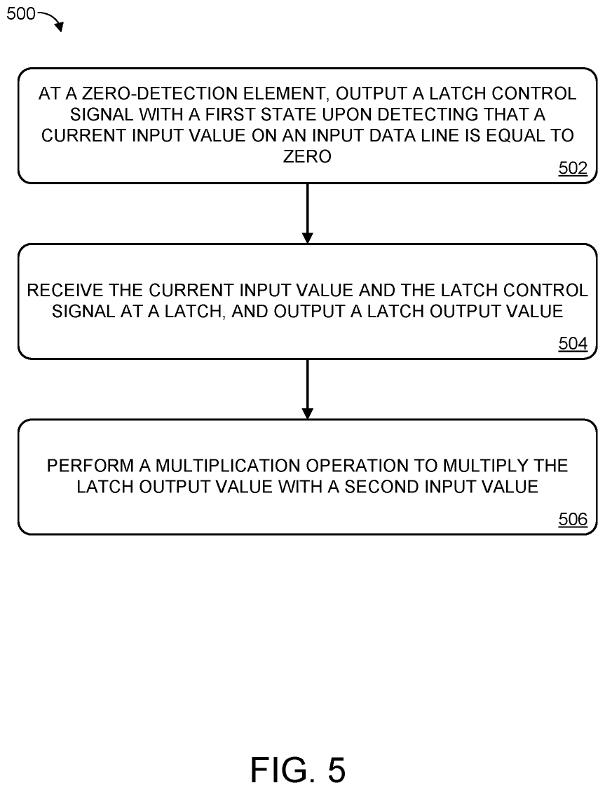

FIG. 5 illustrates an example method 500 for data multiplication in a hardware logic circuit. Method 500 may be implemented in any suitable logic circuit included in any suitable computing device. For instance, steps of method 500 may be implemented in tandem with logic circuit 200 or logic circuit 400, either of which may be integrated into computing system 100 of FIG. 1 and/or computing system 600 of FIG. 6. Steps of method 500 may be initiated, terminated, and/or looped at any suitable time and in response to any suitable condition.

At 502, method 500 includes, at a zero-detection element, outputting a latch control signal with a first state based at least in part on detecting that a current input value on an input data line is equal to zero. For instance, as described above with respect to FIG. 2, zero-detection element 204 outputs a latch control signal 205 based at least in part on detecting that either of the first current input value 203A or the second current input value 203B is equal to zero.

At 504, method 500 includes receiving the current input value and the latch control signal at a latch, and outputting a latch output value. As described above, the latch output value is a prior input value if the latch control signal has the first state, and the latch output value is the current input value if the latch control signal has a second state. In this manner, the inputs to the multiplier (and/or MAC) only change when the current input value is a non-zero value. Otherwise, the input to the multiplier remains the same, beneficially reducing electrical power consumption.

At 506, method 500 includes performing a multiplication operation to multiply the latch output value with a second input value. For instance, as described above, the latch output value may be multiplied with a second latch output value received from a second latch, where the second latch receives a second current input value over a second input data line.

The methods and processes described herein may be tied to a computing system of one or more computing devices. In particular, such methods and processes may be implemented as an executable computer-application program, a network-accessible computing service, an application-programming interface (API), a library, or a combination of the above and/or other compute resources.

FIG. 6 schematically shows a simplified representation of a computing system 600 configured to provide any to all of the compute functionality described herein. Computing system 600 may take the form of one or more personal computers, network-accessible server computers, tablet computers, home-entertainment computers, gaming devices, mobile computing devices, mobile communication devices (e.g., smart phone), virtual/augmented/mixed reality computing devices, wearable computing devices, Internet of Things (IoT) devices, embedded computing devices, and/or other computing devices.

Computing system 600 includes a logic subsystem 602 and a storage subsystem 604. Computing system 600 may optionally include a display subsystem 606, input subsystem 608, communication subsystem 610, and/or other subsystems not shown in FIG. 6.

Logic subsystem 602 includes one or more physical devices configured to execute instructions. For example, the logic subsystem may be configured to execute instructions that are part of one or more applications, services, or other logical constructs. The logic subsystem may include one or more hardware processors configured to execute software instructions. Additionally, or alternatively, the logic subsystem may include one or more hardware or firmware devices configured to execute hardware or firmware instructions. Processors of the logic subsystem may be single-core or multi-core, and the instructions executed thereon may be configured for sequential, parallel, and/or distributed processing. Individual components of the logic subsystem optionally may be distributed among two or more separate devices, which may be remotely located and/or configured for coordinated processing. Aspects of the logic subsystem may be virtualized and executed by remotely-accessible, networked computing devices configured in a cloud-computing configuration.

Storage subsystem 604 includes one or more physical devices configured to temporarily and/or permanently hold computer information such as data and instructions executable by the logic subsystem. When the storage subsystem includes two or more devices, the devices may be collocated and/or remotely located. Storage subsystem 604 may include volatile, nonvolatile, dynamic, static, read/write, read-only, random-access, sequential-access, location-addressable, file-addressable, and/or content-addressable devices. Storage subsystem 604 may include removable and/or built-in devices. When the logic subsystem executes instructions, the state of storage subsystem 604 may be transformed—e.g., to hold different data.

Aspects of logic subsystem 602 and storage subsystem 604 may be integrated together into one or more hardware-logic components. Such hardware-logic components may include program—and application-specific integrated circuits (PASIC/ASICs), program—and application-specific standard products (PSSP/ASSPs), system-on-a-chip (SOC), and complex programmable logic devices (CPLDs), for example.

The logic subsystem and the storage subsystem may cooperate to instantiate one or more logic machines. As used herein, the term “machine” is used to collectively refer to the combination of hardware, firmware, software, instructions, and/or any other components cooperating to provide computer functionality. In other words, “machines” are never abstract ideas and always have a tangible form. A machine may be instantiated by a single computing device, or a machine may include two or more sub-components instantiated by two or more different computing devices. In some implementations a machine includes a local component (e.g., software application executed by a computer processor) cooperating with a remote component (e.g., cloud computing service provided by a network of server computers). The software and/or other instructions that give a particular machine its functionality may optionally be saved as one or more unexecuted modules on one or more suitable storage devices.

Machines may be implemented using any suitable combination of state-of-the-art and/or future machine learning (ML), artificial intelligence (AI), and/or natural language processing (NLP) techniques. Non-limiting examples of techniques that may be incorporated in an implementation of one or more machines include support vector machines, multi-layer neural networks, convolutional neural networks (e.g., including spatial convolutional networks for processing images and/or videos, temporal convolutional neural networks for processing audio signals and/or natural language sentences, and/or any other suitable convolutional neural networks configured to convolve and pool features across one or more temporal and/or spatial dimensions), recurrent neural networks (e.g., long short-term memory networks), associative memories (e.g., lookup tables, hash tables, Bloom Filters, Neural Turing Machine and/or Neural Random Access Memory), word embedding models (e.g., GloVe or Word2Vec), unsupervised spatial and/or clustering methods (e.g., nearest neighbor algorithms, topological data analysis, and/or k-means clustering), graphical models (e.g., (hidden) Markov models, Markov random fields, (hidden) conditional random fields, and/or AI knowledge bases), and/or natural language processing techniques (e.g., tokenization, stemming, constituency and/or dependency parsing, and/or intent recognition, segmental models, and/or super-segmental models (e.g., hidden dynamic models)).

In some examples, the methods and processes described herein may be implemented using one or more differentiable functions, wherein a gradient of the differentiable functions may be calculated and/or estimated with regard to inputs and/or outputs of the differentiable functions (e.g., with regard to training data, and/or with regard to an objective function). Such methods and processes may be at least partially determined by a set of trainable parameters. Accordingly, the trainable parameters for a particular method or process may be adjusted through any suitable training procedure, in order to continually improve functioning of the method or process.

Non-limiting examples of training procedures for adjusting trainable parameters include supervised training (e.g., using gradient descent or any other suitable optimization method), zero-shot, few-shot, unsupervised learning methods (e.g., classification based on classes derived from unsupervised clustering methods), reinforcement learning (e.g., deep Q learning based on feedback) and/or generative adversarial neural network training methods, belief propagation, RANSAC (random sample consensus), contextual bandit methods, maximum likelihood methods, and/or expectation maximization. In some examples, a plurality of methods, processes, and/or components of systems described herein may be trained simultaneously with regard to an objective function measuring performance of collective functioning of the plurality of components (e.g., with regard to reinforcement feedback and/or with regard to labelled training data). Simultaneously training the plurality of methods, processes, and/or components may improve such collective functioning. In some examples, one or more methods, processes, and/or components may be trained independently of other components (e.g., offline training on historical data).

When included, display subsystem 606 may be used to present a visual representation of data held by storage subsystem 604. This visual representation may take the form of a graphical user interface (GUI). Display subsystem 606 may include one or more display devices utilizing virtually any type of technology. In some implementations, display subsystem may include one or more virtual-, augmented-, or mixed reality displays.

When included, input subsystem 608 may comprise or interface with one or more input devices. An input device may include a sensor device or a user input device. Examples of user input devices include a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition.

When included, communication subsystem 610 may be configured to communicatively couple computing system 600 with one or more other computing devices. Communication subsystem 610 may include wired and/or wireless communication devices compatible with one or more different communication protocols. The communication subsystem may be configured for communication via personal-, local- and/or wide-area networks.

This disclosure is presented by way of example and with reference to the associated drawing figures. Components, process steps, and other elements that may be substantially the same in one or more of the figures are identified coordinately and are described with minimal repetition. It will be noted, however, that elements identified coordinately may also differ to some degree. It will be further noted that some figures may be schematic and not drawn to scale. The various drawing scales, aspect ratios, and numbers of components shown in the figures may be purposely distorted to make certain features or relationships easier to see.

In an example, a logic circuit comprises: an input data line; a zero-detection element communicatively coupled to the input data line, the zero-detection element configured to output a latch control signal with a first state based at least in part on detecting that a current input value on the input data line is equal to zero; a latch configured to receive the current input value and output a latch output value, wherein the latch output value is a prior input value based at least in part on the latch control signal having the first state, and wherein the latch output value is the current input value based at least in part on the latch control signal having a second state; and a multiplier to perform a multiplication operation in which the latch output value is multiplied with a second value to output a multiplication result. In this example or any other example, the logic circuit further comprises a multiplication correction element configured to receive the multiplication result from the multiplier, and output a corrected value of zero based at least in part on the latch control signal having the first state. In this example or any other example, the multiplication correction element includes an AND gate, and wherein inputs to the AND gate include the output of the multiplication operation, and the latch control signal. In this example or any other example, the logic circuit further comprises one or more delay cells disposed between the input data line and the latch. In this example or any other example, the logic circuit further comprises a second input data line; and a second latch configured to receive a second current input value from the second input data line and output a second latch output value; and wherein the second value multiplied with the latch output value by the multiplier is the second latch output value. In this example or any other example, the zero-detection element is also communicatively coupled to the second input data line, and outputs the latch control signal with the first state based at least in part on detecting that either or both of the current input value and the second current input value is equal to zero. In this example or any other example, the second latch output value is a second prior input value based at least in part on the latch control signal having the first state, and the second latch output value is the second current input value based at least in part on the latch control signal having the second state. In this example or any other example, the logic circuit further comprises a third input data line; and a third latch configured to receive a third current input value from the third input data line and output a third latch output value; and wherein the multiplier is part of a multiplier-accumulator (MAC) configured to multiply the latch output value with the second latch output value, and add a result of the multiplication operation to the third latch output value as a MAC output value. In this example or any other example, the third latch output value is a third prior input value based at least in part on the latch control signal having the first state, and the third latch output value is the third current input value based at least in part on the latch control signal having the second state. In this example or any other example, the logic circuit further comprises a multiplexer configured to receive the MAC output value and the third current input value, and configured to output the third current input value as a corrected MAC output value based at least in part on the latch control signal having the first state. In this example or any other example, the current input value on the input data line is generated during execution of a machine learning model by a computing system. In this example or any other example, the logic circuit is implemented as part of a logic subsystem of a computing device that includes a systolic array.

In an example, a method for data multiplication in a logic circuit comprises: at a zero-detection element of the logic circuit, outputting a latch control signal with a first state based at least in part on detecting that a current input value on an input data line is equal to zero; at a latch of the logic circuit, receiving the current input value and the latch control signal, and outputting a latch output value, wherein the latch output value is a prior input value based at least in part on the latch control signal having the first state, and wherein the latch output value is the current input value based at least in part on the latch control signal having a second state; and at a multiplier of the logic circuit, performing a multiplication operation to multiply the latch output value with a second value and output a multiplication result. In this example or any other example, the current input value on the input data line is generated during execution of a machine learning model by a computing system. In this example or any other example, the method further comprises, at a multiplication correction element of the logic circuit, receiving the multiplication result, and outputting a corrected value of zero based at least in part on the latch control signal having the first state. In this example or any other example, the second value is a second latch output value received by the multiplier from a second latch of the logic circuit. In this example or any other example, the second latch receives a second current input value from a second input data line of the logic circuit, and outputs the second latch output value, and wherein the second latch output value is a second prior input value based at least in part on the latch control signal having the first state, and the second latch output value is the second current input value based at least in part on the latch control signal having the second state. In this example or any other example, the multiplier is part of a multiplier-accumulator (MAC) of the logic circuit, and wherein the method further comprises, at the MAC, adding a result of the multiplication operation to a third input value as a MAC output value. In this example or any other example, the method further comprises, at a multiplexer of the logic circuit, receiving the MAC output value and the latch control signal, and outputting a corrected MAC output value based at least in part on the latch control signal having the first state.

In an example a logic circuit comprises: a first input data line; a second input data line; a zero-detection element communicatively coupled to the first input data line and the second input data line, the zero-detection element configured to output a latch control signal with a first state based at least in part on detecting that a first current input value on the first input data line is equal to zero, or based at least in part on detecting that a second current input value on the second input data line is equal to zero; a first latch configured to receive the first current input value and output a first latch output value, wherein the first latch output value is a first prior input value based at least in part on the latch control signal having the first state, and wherein the first latch output value is the first current input value based at least in part on the latch control signal having a second state; a second latch configured to receive the second current input value and output a second latch output value, wherein the second latch output value is a second prior input value based at least in part on the latch control signal having the first state, and wherein the second latch output value is the second current input value based at least in part on the latch control signal having the second state; and a multiplier to perform a multiplication operation that multiplies the first latch output value with the second latch output value.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A logic circuit, comprising:
an input data line;
a zero-detection element communicatively coupled to the input data line, the zero-detection element configured to output a latch control signal with a first state based at least in part on detecting that a current input value on the input data line is equal to zero;
a latch configured to receive the current input value and output a latch output value, wherein the latch output value is a prior input value based at least in part on the latch control signal having the first state, and wherein the latch output value is the current input value based at least in part on the latch control signal having a second state; and
a multiplier to perform a multiplication operation in which the latch output value is multiplied with a second value to output a multiplication result.

2. The logic circuit of claim 1, further comprising a multiplication correction element configured to receive the multiplication result from the multiplier, and output a corrected value of zero based at least in part on the latch control signal having the first state.

3. The logic circuit of claim 2, wherein the multiplication correction element includes an AND gate, and wherein inputs to the AND gate include the output of the multiplication operation, and the latch control signal.

4. The logic circuit of claim 1, further comprising one or more delay cells disposed between the input data line and the latch.

5. The logic circuit of claim 1, further comprising a second input data line; and a second latch configured to receive a second current input value from the second input data line and output a second latch output value; and wherein the second value multiplied with the latch output value by the multiplier is the second latch output value.

6. The logic circuit of claim 5, wherein the zero-detection element is also communicatively coupled to the second input data line, and outputs the latch control signal with the first state based at least in part on detecting that either or both of the current input value and the second current input value is equal to zero.

7. The logic circuit of claim 6, wherein the second latch output value is a second prior input value based at least in part on the latch control signal having the first state, and the second latch output value is the second current input value based at least in part on the latch control signal having the second state.

8. The logic circuit of claim 5, further comprising a third input data line; and a third latch configured to receive a third current input value from the third input data line and output a third latch output value; and wherein the multiplier is part of a multiplier-accumulator (MAC) configured to multiply the latch output value with the second latch output value, and add a result of the multiplication operation to the third latch output value as a MAC output value.

9. The logic circuit of claim 8, wherein the third latch output value is a third prior input value based at least in part on the latch control signal having the first state, and the third latch output value is the third current input value based at least in part on the latch control signal having the second state.

10. The logic circuit of claim 8, further comprising a multiplexer configured to receive the MAC output value and the third current input value, and configured to output the third current input value as a corrected MAC output value based at least in part on the latch control signal having the first state.

11. The logic circuit of claim 1, wherein the current input value on the input data line is generated during execution of a machine learning model by a computing system.

12. The logic circuit of claim 1, wherein the logic circuit is implemented as part of a logic subsystem of a computing device that includes a systolic array.

13. A method for data multiplication in a logic circuit, comprising:
at a zero-detection element of the logic circuit, outputting a latch control signal with a first state based at least in part on detecting that a current input value on an input data line is equal to zero;
at a latch of the logic circuit, receiving the current input value and the latch control signal, and outputting a latch output value, wherein the latch output value is a prior input value based at least in part on the latch control signal having the first state, and wherein the latch output value is the current input value based at least in part on the latch control signal having a second state; and
at a multiplier of the logic circuit, performing a multiplication operation to multiply the latch output value with a second value and output a multiplication result.

14. The method of claim 13, wherein the current input value on the input data line is generated during execution of a machine learning model by a computing system.

15. The method of claim 13, further comprising, at a multiplication correction element of the logic circuit, receiving the multiplication result, and outputting a corrected value of zero based at least in part on the latch control signal having the first state.

16. The method of claim 13, wherein the second value is a second latch output value received by the multiplier from a second latch of the logic circuit.

17. The method of claim 16, wherein the second latch receives a second current input value from a second input data line of the logic circuit, and outputs the second latch output value, and wherein the second latch output value is a second prior input value based at least in part on the latch control signal having the first state, and the second latch output value is the second current input value based at least in part on the latch control signal having the second state.

18. The method of claim 13, wherein the multiplier is part of a multiplier-accumulator (MAC) of the logic circuit, and wherein the method further comprises, at the MAC, adding a result of the multiplication operation to a third input value as a MAC output value.

19. The method of claim 18, further comprising, at a multiplexer of the logic circuit, receiving the MAC output value and the latch control signal, and outputting a corrected MAC output value based at least in part on the latch control signal having the first state.

20. A logic circuit, comprising:
a first input data line;
a second input data line;
a zero-detection element communicatively coupled to the first input data line and the second input data line, the zero-detection element configured to output a latch control signal with a first state based at least in part on detecting that a first current input value on the first input data line is equal to zero, or based at least in part on detecting that a second current input value on the second input data line is equal to zero;
a first latch configured to receive the first current input value and output a first latch output value, wherein the first latch output value is a first prior input value based at least in part on the latch control signal having the first state, and wherein the first latch output value is the first current input value based at least in part on the latch control signal having a second state;
a second latch configured to receive the second current input value and output a second latch output value, wherein the second latch output value is a second prior input value based at least in part on the latch control signal having the first state, and wherein the second latch output value is the second current input value based at least in part on the latch control signal having the second state; and
a multiplier to perform a multiplication operation that multiplies the first latch output value with the second latch output value.
